(19) United States
(12) Patent Application Publication
(10) Pub. No.: US 2024/0172545 A1
(43) Pub. Date: May 23, 2024

(54) DISPLAY PANEL, METHOD FOR MANUFACTURING THE SAME, AND DISPLAY APPARATUS

(71) Applicant: Shanghai Tianma Micro-Electronics Co., Ltd., Shanghai (CN)

(72) Inventors: Quanpeng YU, Shanghai (CN); Ming YANG, Shanghai (CN)

(73) Assignee: Shanghai Tianma Micro-Electronics Co., Ltd., Shanghai (CN)

(21) Appl. No.: 18/425,105

(22) Filed: Jan. 29, 2024

(30) Foreign Application Priority Data
Jun. 30, 2023 (CN) 202310804058.0

(51) Int. Cl. H10K 71/20; H10K 59/12; H10K 59/122; H10K 59/126

(52) U.S. Cl. CPC H10K 71/231; H10K 59/1201; H10K 59/122; H10K 59/126

(57) ABSTRACT

A display panel includes a display region and a first layer. In an embodiment, the display region includes a first display sub-region, and the first display sub-region includes at least one light transmission region. In an embodiment, the display panel includes a first layer, at least a part of the first layer is located in the light transmission region. In an embodiment, the first layer includes multiple etching patterns, and the etching patterns at least includes first etching patterns and second etching patterns. In an embodiment, the first etching patterns have a different shape and/or size from the second etching patterns.

### CROSS-REFERENCE TO RELATED DISCLOSURE

The present disclosure claims priority to Chinese Patent Application No. 202310804058.0, filed on Jun. 30, 2023, the content of which is incorporated herein by reference in its entirety.

### TECHNICAL FIELD

The present disclosure relates to a field of display technologies, and in particular, to a display panel, a method for manufacturing a display panel, and a display apparatus.

### BACKGROUND

With continuous development of display technology and the increasing demand for electronic products, a full-screen display has gradually become the development trend of electronic devices such as mobile phones. In addition, in order to enrich the functions of display devices, a high-transmittance area is currently created in the display device to be equipped with photosensitive devices such as cameras and fingerprint sensors. Designing the area with high transmittance for design has become a focus of research for technicians.

### SUMMARY

A first aspect of the present disclosure provides a display panel. In an embodiment, the display panel includes a display region. In an embodiment, the display region includes a first display sub-region, and the first display sub-region includes at least one light transmission region. In an embodiment, the display panel includes a first layer, at least a part of the first layer is located in the at least one light transmission region. In an embodiment, the first layer includes multiple etching patterns, and multiple etching patterns at least includes first etching patterns and second etching patterns. In an embodiment, the first etching patterns have a different shape and/or size from the second etching patterns.

A second aspect of the present disclosure provides a method for manufacturing a display panel. In an embodiment, a display region of the display panel includes a first display sub-region, the first display sub-region includes at least one light transmission region. In an embodiment, the method includes: providing a first layer; and etching the display panel by using laser rays, and forming etching patterns on the first layer, wherein the etching patterns at least include first etching patterns and second etching patterns. The first etching patterns have different shape and/or size from the second etching pattern.

A third aspect of the present disclosure provides a display apparatus. In an embodiment, the display apparatus includes a display panel. In an embodiment, the display panel includes a display region. In an embodiment, the display region includes a first display sub-region, and the first display sub-region includes at least one light transmission region. In an embodiment, the display panel includes a first layer, at least a part of the first layer is located in the at least one light transmission region. In an embodiment, the first layer includes multiple etching patterns, and multiple etching patterns at least includes first etching patterns and second etching patterns. In an embodiment, the first etching patterns have a different shape and/or size from the second etching patterns.

### DRAWINGS

In order to more clearly illustrate the technical solutions in the embodiments of the present disclosure, the accompanying drawings used in the description of the embodiments will be briefly introduced below. The accompanying drawings in the following description are only some embodiments of the present disclosure, and other drawings can be obtained by those skilled in the art from the provided drawings.

FIG. 1 is an enlarged schematic view of a display panel according to some embodiments of the present disclosure;

FIG. 2 is an enlarged schematic view a first display sub-region according to some embodiments of the present disclosure;

FIG. 3 is a cross-sectional view taken along line BB′ in FIG. 2 according to some embodiments of the present disclosure;

FIG. 4 is a partial enlarged schematic view of a display panel according to some embodiments of the present disclosure;

FIG. 5 is a cross-sectional view taken along line CC′ in FIG. 2 according to some embodiments of the present disclosure;

FIG. 6 is a cross-sectional view of another display panel according to some embodiments of the present disclosure;

FIG. 7 is an enlarged schematic view of a light transmission region and its periphery in FIG. 2 according to some embodiments of the present disclosure;

FIG. 8 is an enlarged schematic view of another light transmission region and its periphery in FIG. 2 according to some embodiments of the present disclosure;

FIG. 9 is a schematic diagram showing an etching sequence of a laser spot according to some embodiments of the present disclosure;

FIG. 10 is a schematic diagram showing another etching sequence of a laser spot according to some embodiments of the present disclosure;

FIG. 11 is a schematic diagram showing yet another etching sequence of a laser spot according to some embodiments of the present disclosure;

FIG. 12 is an enlarged schematic view of a light transmission region and its periphery according to some embodiments of the present disclosure;

FIG. 13 is an enlarged schematic view illustrating two light transmission regions including a first etching pattern and a second etching pattern respectively according to some embodiments of the present disclosure;

FIG. 14 is an enlarged schematic view of another light transmission region and its periphery according to some embodiments of the present disclosure;

FIG. 15 is an enlarged schematic view illustrating two light transmission regions including a first etching pattern and a second etching pattern respectively according to some embodiments of the present disclosure;

FIG. 16 is an enlarged schematic view of another light transmission region and its periphery according to some embodiments of the present disclosure;

FIG. 17 is an enlarged schematic view of another light transmission region according to some embodiments of the present disclosure;

FIG. 18 is an enlarged schematic view of another light transmission region and its periphery according to some embodiments of the present disclosure;

FIG. 19 is an enlarged schematic view of another light transmission region and its periphery according to some embodiments of the present disclosure;

FIG. 20 is an enlarged schematic view of another light transmission region and its periphery according to some embodiments of the present disclosure;

FIG. 21 is an enlarged schematic view of another light transmission region according to some embodiments of the present disclosure;

FIG. 22 is an enlarged schematic view of another light transmission region according to some embodiments of the present disclosure;

FIG. 23 is an enlarged schematic view of another light transmission region and its periphery according to some embodiments of the present disclosure;

FIG. 24 is a schematic diagram showing another etching sequence of a laser spot according to some embodiments of the present disclosure;

FIG. 25 is an enlarged schematic view of another light transmission region according to some embodiments of the present disclosure;

FIG. 26 is an enlarged schematic view of another light transmission region according to some embodiments of the present disclosure;

FIG. 27 is a schematic diagram showing distribution of laser spots irradiating a first display sub-region according to some embodiments of the present disclosure;

FIG. 28 is a schematic diagram showing a display apparatus according to some embodiments of the present disclosure; and

FIG. 29 is a cross-sectional view taken along line FF′ in FIG. 28 according to some embodiments of the present disclosure.

### DESCRIPTION OF EMBODIMENTS

In order to better understand the technical solution of the present disclosure, embodiments of the present disclosure are described in detail below with reference to the accompanying drawings.

It should be noted that the described embodiments are merely exemplary embodiments of the present disclosure, which shall not be interpreted as providing limitations to the present disclosure. All other embodiments obtained by those skilled in the art according to the embodiments of the present disclosure are within the scope of the present disclosure.

Terms used in the embodiments of the present disclosure are only for the purpose of describing specific embodiments, and are not intended to limit the present disclosure. Unless otherwise specified in the context, words, such as “a”, “the”, and “this”, in a singular form in the embodiments of the present disclosure and the appended claims include plural forms.

It should be understood that the term “and/or” used herein merely indicates a relationship describing associated objects, indicating three possible relationships. For example, the expression “A and/or B” indicates: A exists alone, both A and B exist, or B exists alone. In addition, the character “/” in this description generally means that the associated objects are in an “or” relationship.

It should be understood that although the terms “first”, “second”, “third”, and so on may be used to describe etching patterns in some embodiments of the present disclosure, these etching patterns should not be limited to these terms. These terms are used only to distinguish different etching patterns from each other. For example, without departing from the scope of the embodiments of the present disclosure, a first etching pattern may also be referred to as a second etching pattern, and similarly, a second etching pattern may also be referred to as a first etching pattern.

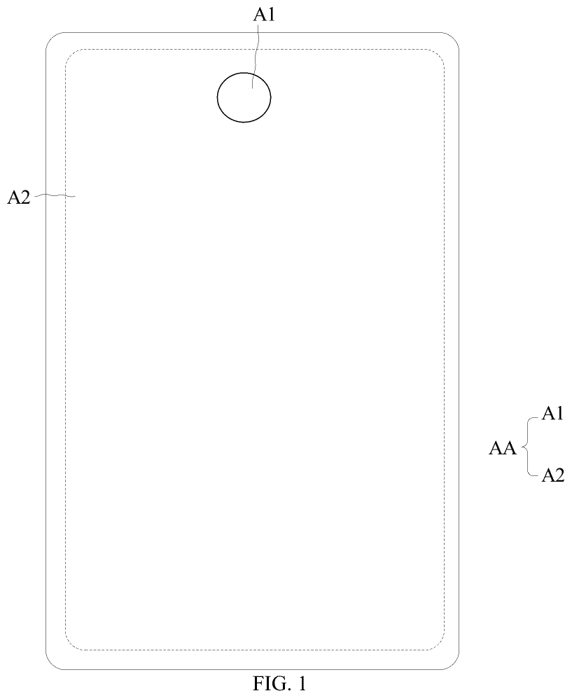

Embodiments of the present disclosure provide a display panel. FIG. 1 is an enlarged schematic view of a display panel according to some embodiments of the present disclosure. As shown in FIG. 1, the display panel includes a display region AA, and the display region AA includes a first display sub-region A1 and a second display sub-region A2. In some embodiments of the present disclosure, the second display sub-region A2 at least partially surrounds the first display sub-region A1. In some embodiments of the present disclosure, a light transmittance of the first display sub-region A1 is greater than a light transmittance of the second display sub-region A2. In some embodiments of the present disclosure, a photosensitive device integrated with an optical sensor such as a camera or an iris recognition structure may be arranged in the first display sub-region A1 subsequently. Accordingly, in addition to the light emitting and display function, the first display sub-region A1 can achieve transmission of optical signals. Therefore, the first display sub-region A1 is provided with biometric recognition functions such as taking photos or identity authentication, enriching the functions of the display panel.

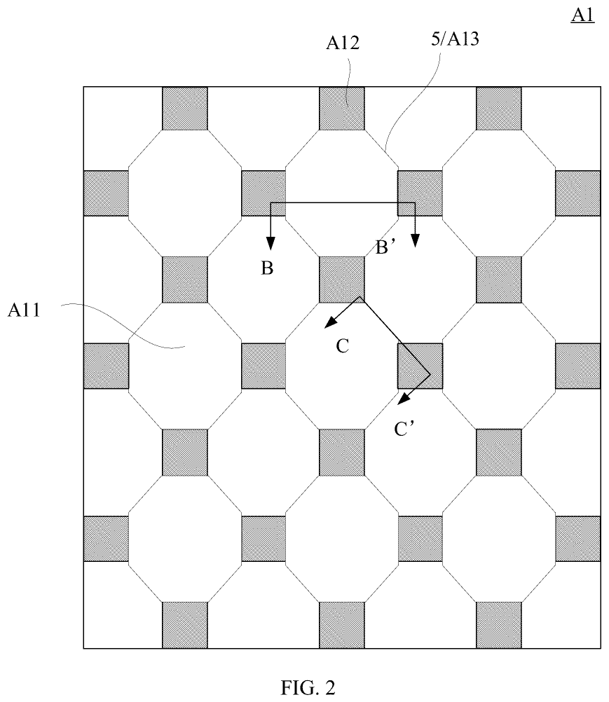

FIG. 2 is an enlarged schematic view of a first display sub-region according to some embodiments of the present disclosure. As shown in FIG. 2, the first display sub-region A1 includes one or more light transmission regions A11 and one or more light-emitting regions A12. The light-emitting region A12 and the second display sub-region A2 both include sub-pixels. In some embodiments of the present disclosure, the light-emitting region A12 includes one or more sub-pixels. In some embodiments of the present disclosure, no sub-pixel is arranged in the light transmission region A11. When the display panel is displaying, the first display sub-region A1 and the second display sub-region A2 both can display, so the area of the region capable of displaying in the display panel is increased. In some embodiments of the present disclosure, the sub-pixel includes a light-emitting element and a pixel drive circuit electrically connected to the light-emitting element. The light-emitting element includes but is not limited to an organic light emitting diode (OLED), a Mini LED or Micro LED, and a quantum dot light emitting diode (QLED). In some embodiments of the present disclosure, the pixel drive circuit has a “7T1C” structure including 7 thin film transistors and 1 storage capacitor, or has a “2T1C” structure including 2 thin film transistors and 1 storage capacitor. Herein, “T” represents the thin film transistor, and “C” represents the capacitor.

It should be noted that, the shape and area of the light-emitting region A12 and the shape and area of the light transmission region A11 shown in FIG. 2 are examples for illustration. The shapes and/or areas of the light-emitting region A12 and the light transmission region A11 can be adjusted according to different design needs in embodiments of the present disclosure.

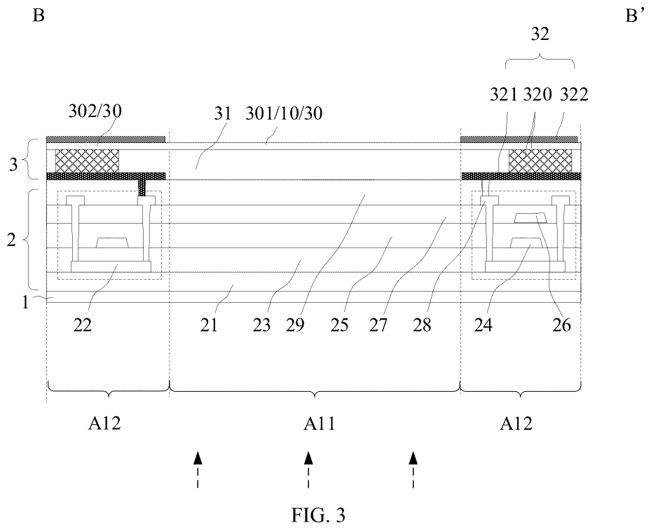

FIG. 3 is a cross-sectional view of the display panel taken along line BB′ in FIG. 2. As shown in FIG. 3, the display panel further includes a substrate 1, an array layer 2, and a display layer 3. The array layer 2 includes the above pixel drive circuits. In some embodiments of the present disclosure, the array layer 2 includes a buffer layer 21, an active layer 22 including a channel of the thin film transistor, a gate insulation layer 23, a gate layer 24 including a gate electrode of the thin film transistor, an inter-metal insulation layer 25, a capacitor metal layer 26 including one electrode of the capacitor, an interlayer insulation layer 27, a source-drain layer 28 including a source electrode and a drain electrode of the thin film transistor, and a planarization layer 29.

The display layer 3 includes a pixel definition layer 31 and the above light-emitting element 32. The light-emitting element 32 includes an anode 321, a display function layer 320, and a cathode layer 322. The anode 321 is located on the planarization layer 29. The pixel definition layer 31 includes openings. The opening exposes at least a part of the anode 321. In some embodiments of the present disclosure, the display function layer 320 includes one of or a combination of two or more of: a light-emitting layer, a hole transport layer, a hole injection layer, an electron transport layer, and an electron injection layer. Each of the hole transport layer, the hole injection layer, the electron transport layer, and the electron injection layer may be formed as a common layer covering the display region AA and being continuous in different light-emitting elements. At least a part of the light-emitting layer is located in the opening. In some embodiments of the present disclosure, the light-emitting elements 32 include a first light-emitting element positioned in the light-emitting region and a second light-emitting element positioned in the second display sub-region.

As shown in FIG. 3, the display panel further includes a first layer 10. The first layer 10 is located at one side of the substrate 1. At least a part of the first layer 10 is located in the light transmission region A11.

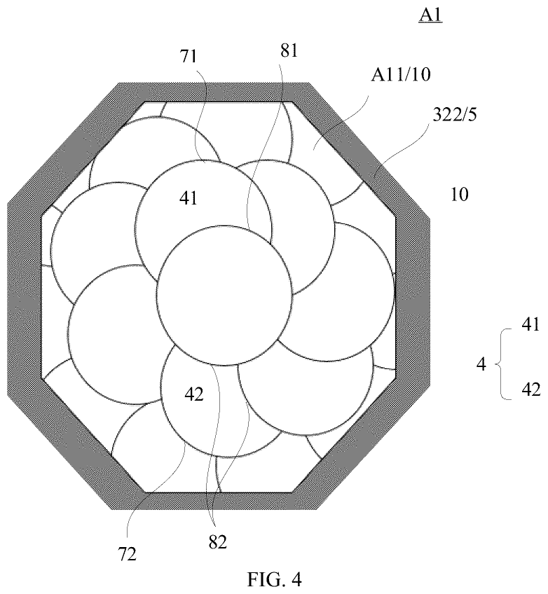

FIG. 4 is a partial enlarged schematic view of a display panel according to some embodiments of the present disclosure. As shown in FIG. 4, the first layer 10 includes multiple etching patterns 4. The etching pattern 4 may be a remaining pattern on a surface of the first layer 10 generated due to a patterning process. In some embodiments of the present disclosure, the patterning process includes laser etching. Accordingly, the etching pattern 4 may be a remaining pattern on the surface of the first layer 10 after some layers of the display panel are etched by laser rays.

In some embodiments of the present disclosure, the first layer 10 includes multiple etching patterns 4. That is, the number of the etching patterns 4 is diverse. Accordingly, an etching process of the display panel have diversified designs in embodiments of the present disclosure. The etch effect of the display panel is ensured, the etching efficiency of the display panel is improved, and the display effect of the display panel and the performance of the photosensitive device are ensured. For example, the diversified designs of the etching process include diversified designs of a movement path of the etching process and/or diversified designs of a density of laser spots and shapes of the laser spot, which are not limited in the present disclosure.

In some embodiments of the present disclosure, there is no light-emitting element arranged in the light transmission region A11. In some embodiments of the present disclosure, the cathode 322 is arranged to avoid the light transmission region A11. For example, the cathode 322 is only arranged in the light-emitting region A12 and the second display sub-region A2.

In some embodiments of the present disclosure, in order to increase the light transmittance of the light transmission region A11, some layers that have a lower light transmittance are patterned, such that these layers are hollowed in the light transmission region A11. For example, the patterning process includes lithography. Hereinafter, these layers are also referred to as to-be-etched layers. In the patterning process of the to-be-etched layers, the to-be-etched layers are irradiated by laser rays in some embodiments of the present disclosure. That is, the to-be-etched layers are subjected to an exposing treatment, such that parts of the to-be-etched layers in the light transmission region A11 are irradiated by the laser rays and removed by the laser rays. Other parts of the to-be-etched layers outside the light transmission region A11, such as the to-be-etched layers in the light-emitting region A12, are not irradiated by the laser and remained in the subsequent process. In FIG. 3, the dashed line with an arrow denotes the laser ray. In some embodiments of the present disclosure, the laser ray may vertically irradiate the to-be-etched layers from the side of the substrate 1 away from the to-be-etched layers.

In the patterning process, one or more layers (for example, a layer in contact with the to-be-etched layer) in the display panel other than the to-be-etched layers is also irradiated by laser rays. Due to the irradiation of laser rays, etching patterns are generated on the one or more layers. After the etching of the to-be-etched layers is complete, the layer including the etching patterns and remained in the display panel is the first layer 10.

The formation of the cathode 322 in the light-emitting element 32 is taken as an example. In some embodiments of the present disclosure, in the formation of the cathode 322, an initial cathode layer having an entire planar structure is formed by a film formation. The entire planar structure means that an orthographic projection of the initial cathode layer on the plane of the substrate 1 covers the first display sub-region A1 and the second display sub-region A2. In other words, the initial cathode layer has no hollowed portion. After the initial cathode layer is formed, a portion of the initial cathode layer corresponding to the light transmission region A11 is removed through the patterning process. In this regard, the initial cathode layer is the to-be-etched layer.

In the process of etching the initial cathode layer, in the display panel, a cathode contact layer 30 and a pixel definition layer 31 that are close to the initial cathode layer are also irradiated by laser rays. The cathode contact layer 30 is a layer that is in contact with the initial cathode layer in the manufacturing process of the display panel.

In some embodiments of the present disclosure, the cathode contact layer 30 includes at least one of the display function layer 320. For example, the cathode contact layer 30 includes the electron injection layer or the electron transport layer.

In some embodiments of the present disclosure, as shown in FIG. 3, the cathode contact layer 30 includes a first portion 301 in the light transmission region A11 and a second portion 302 in the light-emitting region A12. At least part of the second portion 302 is in contact with the cathode 322. In some embodiments of the present disclosure, the first portion 301 includes the first layer 10.

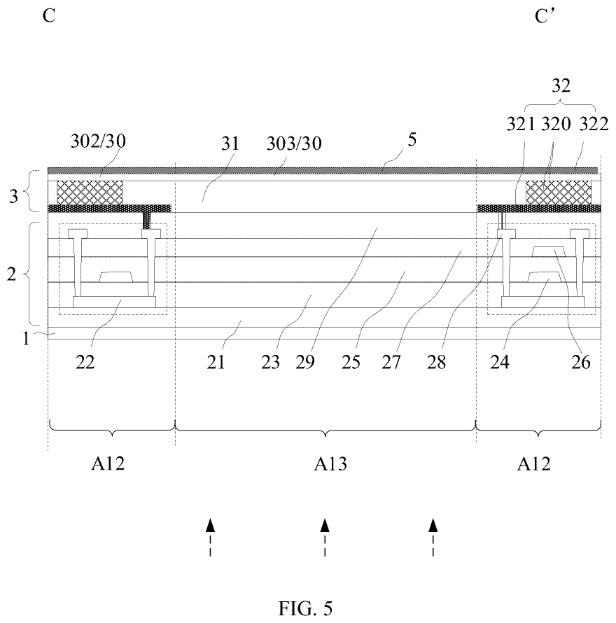

In some embodiments of the present disclosure, as shown in FIG. 2, the first display sub-region A1 further includes a connection region A13 between two adjacent light-emitting regions A12. The connection region A13 includes a connection portion 5. Cathodes 322 in different light-emitting regions A12 are connected by the connection portion 5 to reduce a voltage drop of a cathode signal during transmission. FIG. 5 is a cross-sectional view taken along line CC′ in FIG. 2. As shown in FIG. 5, the cathode contact layer 30 further includes a third sub-portion 303 located in the connection region A13, and the third sub-portion 303 is in contact with the connection portion 5.

In some embodiments of the present disclosure, as shown in FIG. 4, the cathode 322 or the connection portion 5 at least partially surrounds the light transmission region A11,

It should be noted that in the process of etching layers other than the initial cathode layer in the display panel to pattern these layers, the etching patterns generated by the etching may be remained in layers other than the cathode contact layer 20 and the pixel definition layer 31 in the display panel. In some embodiments of the present disclosure, any layer having the etching pattern generated by etching can be referred to as the first layer 10.

In some embodiments of the present disclosure, an organic layer such as a planarization layer and the pixel definition layer 31 in the light transmission layer A11 is also removed, and thus the light transmittance of the light transmission layer A11 is further improved.

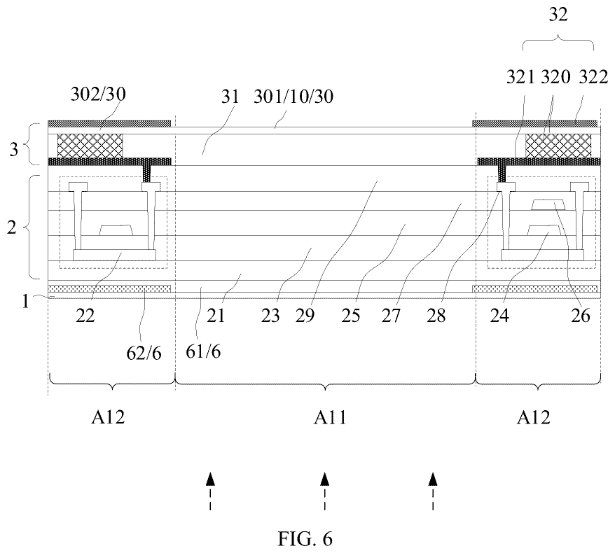

FIG. 6 is a cross-sectional view of another display panel according to some embodiments of the present disclosure. In some embodiments of the present disclosure, as shown in FIG. 6, the display panel further includes a shielding layer 6. The shielding layer 6 is located at a side of the first layer 10 facing toward the substrate 1. The shielding layer 6 includes a hollowed portion 61 and a non-hollowed portion 62. In the etching process of the display panel, the hollowed portion 61 allows laser rays to pass through, and the non-hollowed portion 62 blocks laser rays. Along the direction perpendicular to the plane of the substrate 1 (the thickness direction of the display panel), the hollowed portion 61 at least partially overlaps with the light transmission region A11. In some embodiments of the present disclosure, the shielding layer 6 prevents the laser rays from etching, in the patterning process, a structure that needs to be kept in the final display panel.

For example, as shown in FIG. 4, multiple etching patterns 4 at least include a first etching pattern 41 and a second etching patterns 42. The first etching pattern 41 and the second etching pattern 42 have different shapes, and/or, the first etching pattern 41 and the second etching pattern 42 have different sizes. The configuration that the first etching pattern 41 and the second etching pattern 42 have different sizes includes: the first etching pattern 41 and the second etching pattern 42 having different lengths along a same direction that is parallel to the plane of the substrate 1, and/or, the orthographic projection of the first etching pattern 41 on the plane of the substrate 1 and the orthographic projection of second first etching pattern 42 on the plane of the substrate 1 have different areas.

In some embodiments of the present disclosure, the first etching pattern 41 and the second etching pattern 42 are different in at least one of shape or size, so the designs of the etching patterns 4 are diversified, and different etching patterns 4 are irregularly distributed in the first display sub-region A. When the external light passes through the first display sub-region A1, the diffraction phenomenon can be weakened or even eliminated, thereby improving the performance of the photosensitive device.

The etching patterns 4 having different shapes and or sizes are arranged in embodiments of the present disclosure. Accordingly, in the etching process of the display panel, laser spots having different shapes and/or sizes are employed to etch the to-be-etched layer. Compared with the etching method using a laser spot with a fixed size or shape, embodiments of the present disclosure have an advantage of improving the etching efficiency while ensuring the etching effect, so the manufacturing of the display panel is more efficient. Generally, by adjusting the sizes and/or the shapes of the etching patterns 4, the etching process having etching patterns 4 with different sizes and/or shapes is simpler and more efficient, reducing the manufacturing cost of the display panel.

In some embodiments of the present disclosure, as shown in FIG. 4, the same light transmission region A11 includes the first etching pattern 41 and the second etching pattern 42 having different shapes and/or different sizes. Therefore, the irregular distribution of the etching patterns in the same light transmission region A11 is increased, and the diffraction problem is significantly reduced.

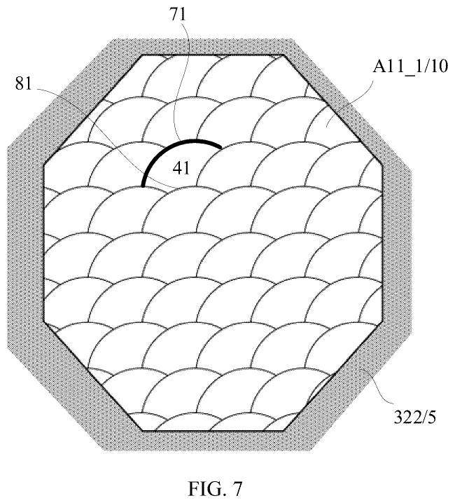

In some embodiments of the present disclosure, as shown in FIG. 2, the first display sub-region A1 includes at least two light transmission regions A11. FIG. 7 is an enlarged schematic view of a light transmission region and its periphery in FIG. 2. FIG. 8 is an enlarged schematic view of another light transmission region and its periphery in FIG. 2. As shown in FIG. 7 and FIG. 8, the light transmission region A11 shown in FIG. 7 includes the first etching patterns 41, and the light transmission region A11 shown in FIG. 8 includes the second etching patterns 42. Herein, the light transmission region including the first etching patterns 41 is denoted as the first light transmission region A11_1, and the light transmission region including the second etching patterns 42 is denoted as the second light transmission region A11_2. In this embodiment, the first etching pattern 41 and the second etching pattern 42 having different shapes and/or different sizes are respectively located in different light transmission regions A11, which can reduce or even eliminate the diffraction problem when external light passes through the first display sub-region A1. For example, as shown in FIG. 7, the first light transmission region A11 includes multiple first etching patterns 41. And/or, as shown in FIG. 8, the second light transmission region A11 includes multiple second etching patterns 42. With such arrangement, in the etching process of the display panel using laser rays, the etching process may be performed with same etching parameters in a region corresponding to one light transmission region A11, so frequent adjusting of the etching parameters is not needed, and the manufacturing process of the display panel is reduced.

In some embodiments of the present disclosure, one or more etching patterns 4 have an edge at least a part of which is a convex arc. The convex arc refers to an arc that is convex along a direction away from a center of the etching pattern. As shown in FIG. 7, the edge of the first etching pattern 41 includes a first convex arc 71. As shown in FIG. 8, the edge of the second etching pattern 42 includes a second convex arc 72. The first convex arc 71 and the second convex arc 72 are convex in different directions of the first etching pattern 41 and the second etching pattern 42. FIG. 7 shows an example in which the first convex arc 71 is on the left side of the first etching pattern 41. FIG. 8 shows an example in which the second convex arc 72 is on the right side of the second etching pattern 42. With such arrangement, the complex degree of patterns in the first display sub-region A1 is increased, thereby reducing or even eliminating the diffraction problem when external light passes through the first display sub-region A1.

In some embodiments of the present disclosure, the shapes of the etching patterns are adjusted by adjusting the shapes of the laser spots of the moving sequence/path of the laser spots.

In some embodiments of the present disclosure, when the display panel is irradiated by laser rays, the shape of the remaining pattern on the first layer 10 generated by the laser spot is approximate to or the same as the shape of the laser spot. For example, when the shape of the laser spot is circular, the shape of the remaining pattern generated by the laser spot is also circular.

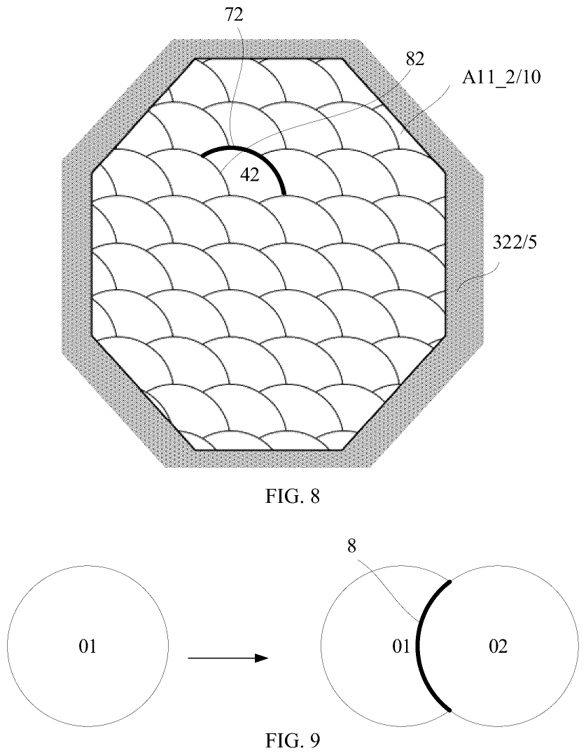

If the orthographic projections of two laser spots on the first layer 10 have an overlapping, the remaining patterns generated by the two laser spots also have an overlapping. A part of the remaining patterns formed earlier will be covered by a part of the remaining pattern formed latter. FIG. 9 is a schematic diagram showing an etching sequence of laser spots according to some embodiments of the present disclosure. FIG. 9 shows an illustration example of two remaining patterns generated by two laser spots. As shown in FIG. 9, the two remaining patterns are denoted as a first initial etching pattern 01 and a second initial etching pattern 02 respectively. A part of the first initial etching pattern 01 is covered by the second initial etching pattern 02, so the circular-shaped second initial etching pattern 02 exhibits a crescent-shaped etching pattern in the first layer 10.

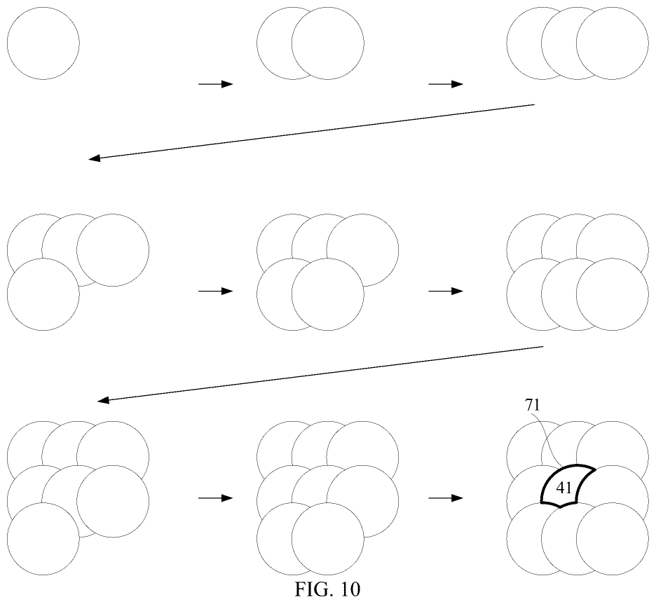

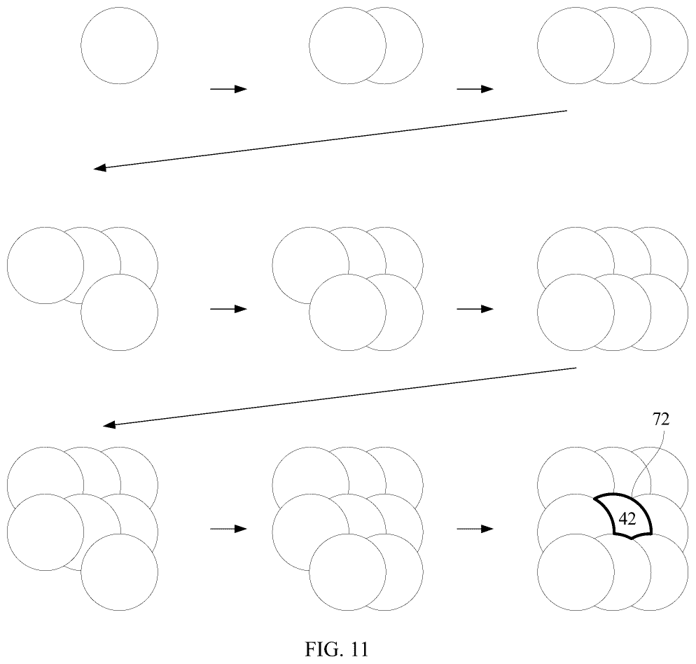

In some embodiments of the present disclosure, the first etching patterns 41 having the shapes in FIG. 7 may be formed by irradiating the display panel using multiple laser spots sequentially according to the sequence shown in FIG. 10. FIG. 10 is a schematic diagram showing another etching sequence of laser spots according to some embodiments of the present disclosure. In some embodiments of the present disclosure, the second etching patterns 42 having the shapes in FIG. 8 may be formed by irradiating the display panel using multiple laser spots sequentially according to the sequence shown in FIG. 11. FIG. 11 is a schematic diagram showing yet another etching sequence of laser spots according to some embodiments of the present disclosure. With such arrangement, the diffraction problem when external light passes through the first display sub-region A1 is reduced, some laser spots having adjacent irradiation positions are emitted one by one according to a chronological order, thereby improving the process efficiency.

In some embodiments of the present disclosure, at least one edge of at least one etching pattern 4 is arranged to be a non-convex arc. In some embodiments of the present disclosure, the non-convex arc includes a straight line and/or a concave arc. Herein, a concave arc refers to an arc concaved to the center of the etching pattern. As shown in FIG. 9, the non-convex arc 8 may correspond an edge of an overlapping portion between two adjacent laser spots, and the edge is adjacent to one of the two adjacent laser spots which is formed firstly.

In some embodiments of the present disclosure, the edge of the first etching pattern 41 includes at least one first non-convex arc 81 as shown in FIG. 7, and the edge of the second etching pattern 42 includes at least one second non-convex arc 82.

In some embodiments of the present disclosure, as shown in FIG. 7 and FIG. 8, the number of the first non-convex arc 81 is equal to the number of the second non-convex arc 82, and the number of the first convex arc 71 is equal to the number of the second convex arc 72. In other words, through translation and rotation, one of the first etching pattern 41 and the second etching pattern 42 may coincide with the other one of the first etching pattern 41 and the second etching pattern 42. It should be noted that, in some embodiments of the present disclosure, the expression the first etching pattern 41 and the second etching pattern 42 have different shapes does not include the situation that one of the first etching pattern 41 and the second etching pattern 42 may coincide with the other one of the first etching pattern 41 and the second etching pattern 42 though translation and rotation, whereas the expression the first etching pattern 41 and the second etching pattern 42 have a same shape only includes the situation that one of the first etching pattern 41 and the second etching pattern 42 may coincide with the other one of the first etching pattern 41 and the second etching pattern 42 though translation and rotation.

In some embodiments of the present disclosure, the number of the first non-convex arc 81 is different from the number of the second non-convex arc 82, and thus the shape of the first etching pattern 41 is different from the shape of the second etching pattern 42, and the distribution of the etching patterns is diversified. In the illustrative example shown in FIG. 4, the number of the first convex arc 71 of the first etching pattern 41 is 1, the first non-convex arc 81 of the first etching pattern 41 is 1, the second convex arc 72 of the second etching pattern 42 is 1, and the second non-convex arc 82 of the second etching pattern 42 is 2.

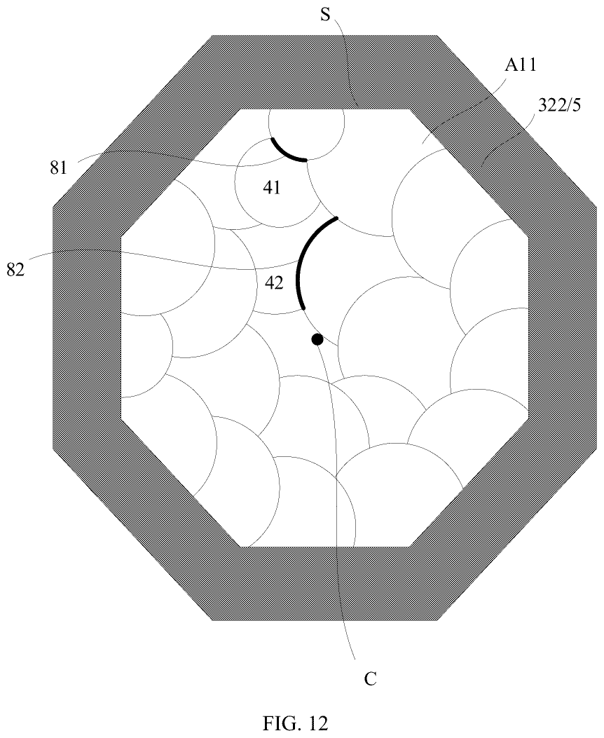

FIG. 12 is an enlarged schematic view of a light transmission region and its periphery according to some embodiments of the present disclosure. In some embodiments of the present disclosure, as shown in FIG. 12, the number of the first non-convex arc 81 of the first etching pattern 41 is smaller than the number of the second non-convex arc 82 of the second etching pattern 42, and the first etching pattern 41 is positioned at a side of the second etching pattern 42 away from the center C of the light transmission region A11. In some embodiments of the present disclosure, the first etching pattern 41 having a smaller quantity of non-convex arc is positioned at a side of the second etching pattern 42 having a greater quantity of non-convex arc away from the center C of the light transmission region A11. For example, during the manufacturing of the display panel, the laser etching may be carried out in the following sequence, first irradiating a region close to the center C of the light transmission region A11, and then irradiating a region close to the edge of the light transmission region A11. In addition, orthographic projections of two adjacent laser spots on the first layer 10 at least partially overlap with each other. In this way, completion of an etching is ensured.

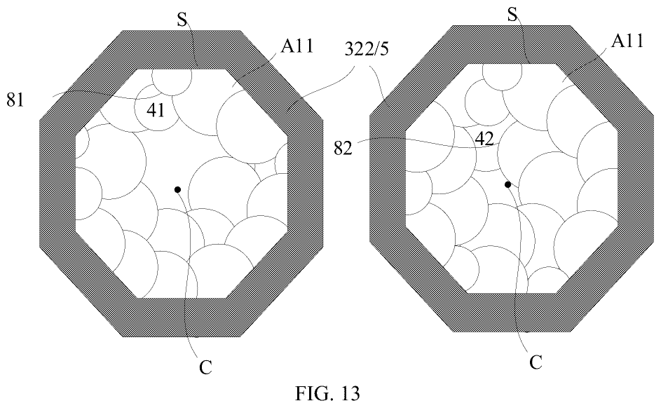

In some embodiments of the present disclosure, as shown in FIG. 12, the first etching pattern 41 and the second etching pattern 42 with different numbers of non-convex arcs are located in the same light transmission region A11. In another embodiment, the first etching pattern 41 and the second etching pattern 42 with different numbers of non-convex arcs are located in different light transmission regions A11. FIG. 13 is an enlarged schematic view illustrating two light transmission regions including a first pattern and a second pattern respectively. In some embodiments of the present disclosure, as shown in FIG. 13, the number of the non-convex arc of the first etching pattern 41 is smaller than the number of the non-convex arc of the second etching pattern 42, and the distance between the first etching pattern 41 and the center of the light transmission region A11 where the first etching pattern 41 is located is greater than the distance between the second etching pattern 42 and the center of the light transmission region A11 where the second etching pattern 42 is located.

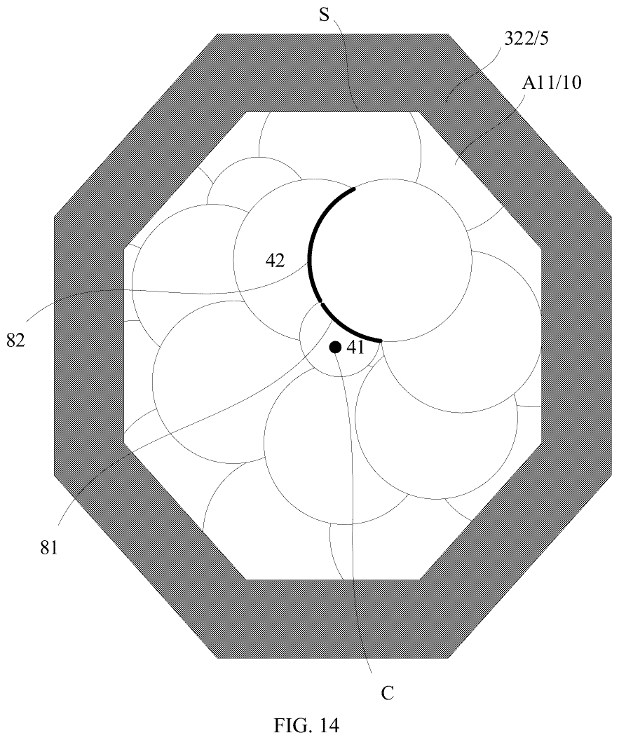

FIG. 14 is an enlarged schematic view of another light transmission region and its periphery according to some embodiments of the present disclosure. In some embodiments of the present disclosure, as shown in FIG. 14, the number of the first non-convex arc 81 in the first etching pattern 41 is smaller than the number of the second non-convex arc 82 in the second etching pattern 42, and the first etching pattern 41 is located at a side of the second etching pattern 42 away from the edge of the light transmission region A11. In other words, the first etching pattern 41 is located at a side of the second etching pattern 42 facing toward the center C of the light transmission region A11. In this embodiment, the first etching pattern 41 with a smaller number of non-convex arc is located at a side of the second etching pattern 42 with a larger number of non-convex arc adjacent to the center C of the light transmission region A11. For example, in the manufacturing of the display panel, the etching process may be carried out in the following sequence: first irradiating a region of the light transmission region A11 adjacent to the edge S, and then irradiating a region of the light transmission region A11 adjacent to the center C. In addition, the orthographic projections of two adjacent laser spots on the first layer 10 at least partially overlap with each other, which can ensure the etching completeness.

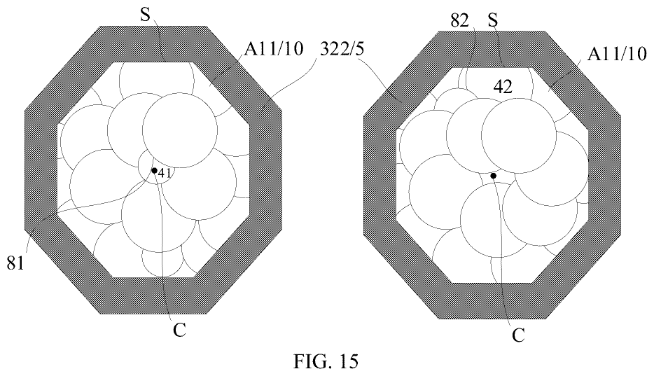

In some embodiments of the present disclosure, as shown in FIG. 14, the first etching pattern 41 and the second etching pattern 42 with different numbers of non-convex arcs are located in the same light transmission region A11. In another embodiment, the first etching pattern 41 and the second etching pattern 42 with different numbers of non-convex arcs are located in different light transmission regions A11. FIG. 15 is an enlarged schematic view illustrating two light transmission regions including a first pattern and a second pattern respectively. In the exemplary embodiment in which the first etching pattern 41 and the second etching pattern 42 are located in different light transmission regions A11, as shown in FIG. 15, the number of the non-convex arc of the first etching pattern 41 is smaller than the number of the non-convex arc of the second etching pattern 42, and the distance between the first etching pattern 41 and the center of the light transmission region A11 where the first etching pattern 41 is located is smaller than the distance between the second etching pattern 42 and the center of the light transmission region A11 where the second etching pattern 42 is located.

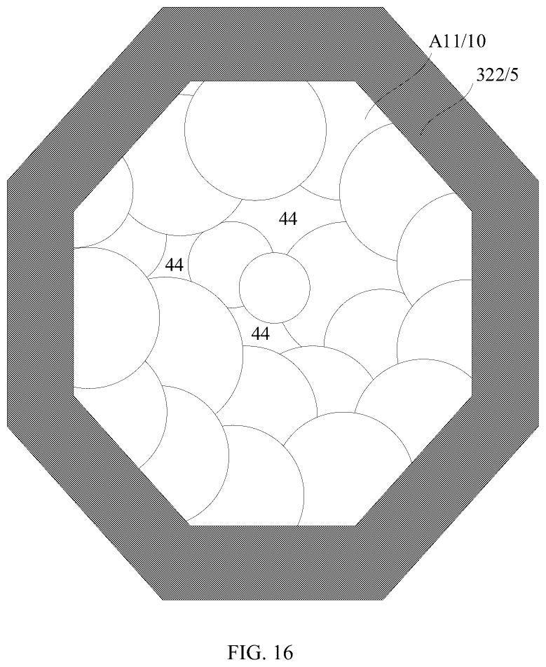

In some embodiments of the present disclosure, at least one light transmission region each includes multiple fourth etching patterns 44 located therein, and an edge of each fourth etching pattern 44 does not include the convex arc. FIG. 16 is an enlarged schematic view of another light transmission region and its periphery according to some embodiments of the present disclosure. In the example embodiment shown in FIG. 16, the light transmission region A11 includes three fourth etching patterns 44, and the edge of each fourth etching pattern 44 does not include the convex arc.

In the manufacturing of the display panel including the first layer having the structure shown in FIG. 16, the laser spot corresponding to the center of the fourth etching pattern 44 is surrounded by other laser spots, and the laser spot corresponding to the center of the fourth etching pattern 44 irradiates the first layer 10 earlier than other laser spots. With such arrangement, the shapes of the fourth etching pattern 44 are diversified, the diffraction problem in the first display sub-region A1 is reduced, a situation that a certain region is not etched by the laser spot is avoided, the etching completeness is increased, and the light transmittance of the light transmission region A11 is increased.

In some embodiments of the present disclosure, the arrangement of the etching patterns 4 on the first layer 10 represents an etching path of laser spots in the etching process. For example, multiple etching patterns 4 are arranged in a curve, and the laser etching is carried out along a curve, so the region requiring laser etching is etched well. The etching path based on a curve can ensure the region requiring etching is completely removed, residual is avoided, and the overall display and the light transmission effect of the display panel are ensured.

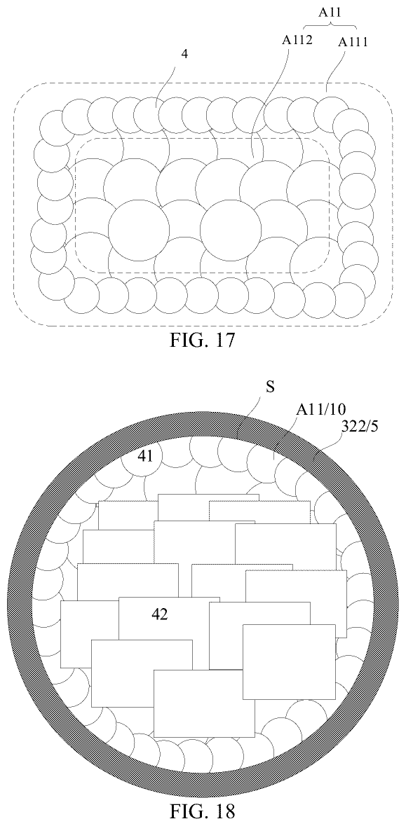

FIG. 17 is an enlarged schematic view of another light transmission region according to some embodiments of the present disclosure. In some embodiments of the present disclosure, as shown in FIG. 17, the light transmission region A11 includes a first region A111 and a second region A112. A density of the etching pattern 4 in the first region A111 is different from a density of the etching pattern 4 in the second region A112. In this way, the distribution of the etching pattern 4 in the light transmission region A11 is diversified, the diffraction law is destroyed, and the diffraction problem when the external light passes through the first display sub-region A1 is reduced or even eliminated.

In some embodiments of the present disclosure, as shown in FIG. 17, the density of the etching pattern 4 in the first region A111 is greater than the density of the etching pattern 4 in the second region A112, and the first region A111 is located at a side of the second region A112 away from the center of the light transmission region A11. That is, the density of the etching patterns 4 in the first region A111 that is farther from the center of the light transmission region A11 is larger, which ensures the laser energy received by the first region A111 closer to the edge. In this way, the portion of the to-be-etched layer adjacent to the edge in the light transmission region A11 can be removed, thereby increasing the light transmittance of the first region A111 that is adjacent to the edge.

In addition, through making the two regions have different etching pattern densities, the shapes of the etching patterns are different. This is because in the region having a larger etching pattern density, the mutual shielding degree of the etching patterns is larger. In other words, one etching pattern may overlap with more etching patterns, and thus the number of non-convex arc in this etching pattern is different from that of a etching pattern in the region having a smaller etching pattern density. In addition, edge diffraction needs to be improved with more attention. By increasing the density of the etching patterns in the edge region of the light transmission region, the pattern of the etching patterns in the edge region is more complex and out-of-order, and the improvement to the diffraction problem is more uniform for the entire light transmission region.

In some embodiments of the present disclosure, as shown in FIG. 17, the first region A111 and the second region A112 are located in the same light transmission region A11, or the first region A111 and the second region A112 are located in different light transmission regions A11. For example, when the first region A111 and the second region A112 are located in different light transmission regions A11, the distance between the first region A111 and the center C of the light transmission region A11 where the first region A111 is located is greater than the distance between the second region A112 and the center C of the light transmission region A11 where the second region A112 is located.

In some embodiments of the present disclosure, the shape of the first etching pattern 41 and the shape of the second etching pattern 42 are different, and the first etching pattern 41 is located at a side of the second etching pattern 42 facing toward the edge of the light transmission region A11. That is, two etching patterns 4 having different positions relative to the edge of the light transmission region A11 have different shapes, so the shape of the etching pattern 4 matches the distance between the etching pattern 4 and the edge of the light transmission region A11.

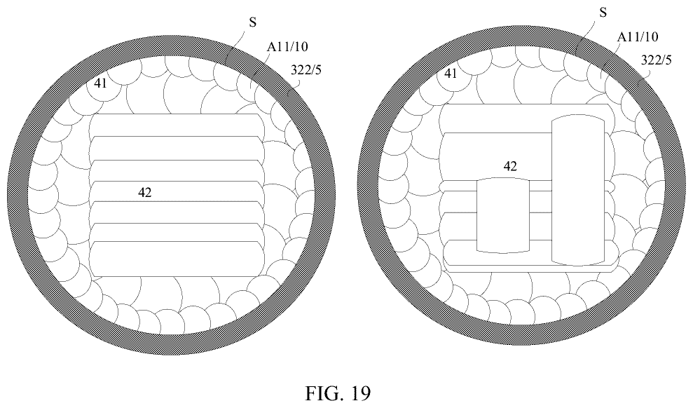

FIG. 18 is an enlarged schematic view of another light transmission region and its periphery according to some embodiments of the present disclosure. In some embodiments of the present disclosure, as shown in FIG. 18, the first etching pattern 41 includes a dot-shaped etching pattern, and the second etching pattern 42 includes a block-shaped etching pattern. Therefore, the shape of the first etching pattern 41 and the shape of the second etching pattern 42 are different, the patterns of the etching patterns are diversified. FIG. 19 is an enlarged schematic view of another light transmission region and its periphery according to some embodiments of the present disclosure. In some alternative embodiments, as shown in FIG. 19, the first etching pattern 41 includes a dot-shaped etching pattern, and the second etching pattern 42 includes a strip-shaped etching pattern. FIG. 19 shows an example in which two types of strip-shaped etching patterns having different regularities.

In some embodiments of the present disclosure, the first etching pattern 41 includes a dot-shaped etching pattern, and the second etching pattern 42 includes a block-shaped etching pattern or a strip-shaped etching pattern, the dot-shaped etching pattern can better match the edge S of the light transmission region A11, and the block-shaped etching pattern and the strip-shaped etching pattern have a larger covering area, so everywhere in the light transmission region A11 that needs to be etched is provide with the etching pattern 4, the etching efficiency and the uniformity of the etching patterns after etching are improved, and over etching and insufficient etching are avoided.

In view of the above, in some embodiments of the present disclosure, the diversity of the etching is improved by adjusting the shapes of the etching pattern 4, thereby ensuring the etching effect of the display panel, ensuring the display effect of the display panel, and reducing or even eliminating the diffraction problem when external light passes through the first display sub-region A1. In addition, in some embodiments of the present disclosure, based on actual etching requirements, the etching patterns are arranged in different shapes including the dot-shaped etching pattern, the block-shaped etching pattern or the strip-shaped etching pattern, the etching process is simpler and more effective, and manufacturing cost of the display panel is reduced.

In some embodiments of the present disclosure, the first etching pattern 41 and the second etching pattern 42 have different shapes and/or sizes, possible diffractions under different sizes can be improved, and the diffraction light under different diffraction conditions is avoided in different diffraction conditions.

In some embodiments of the present disclosure, the size of the first pattern 41 is different from the size of the second pattern 42, and the first pattern 41 is located at the side of the second pattern 41 facing toward the edge of the light transmission region A11. That is, the first etching pattern 41 and the second etching pattern 42 having different positions relative to the edge of the edge of the light transmission region A11 have different sizes, so the size of the etching pattern 4 matches the distance between the etching pattern 4 and the edge of the light transmission region A11. In actual etching design, according to the embodiments of the present disclosure, the size of each etching pattern 4 is designed according to its position in the light transmission region A11, or the position of each etching pattern 4 in the light transmission region A11 is designed according to its size. In this way, the diffraction problem when external light passes through the first display sub-region A1 is reduced or even eliminated, the etching efficiency and the uniformity of the etching patterns after etching are improved, and over etching and insufficient etching are avoided.

In some embodiments of the present disclosure, as shown in FIG. 18 and FIG. 19, the size of the first etching pattern 41 is smaller than the size of the second etching pattern 42. For example, the area of the first etching pattern 41 is smaller than the area of the second etching pattern 42. In this way, the first etching pattern 41 with a smaller size can better match the edge of the light transmission region A11.

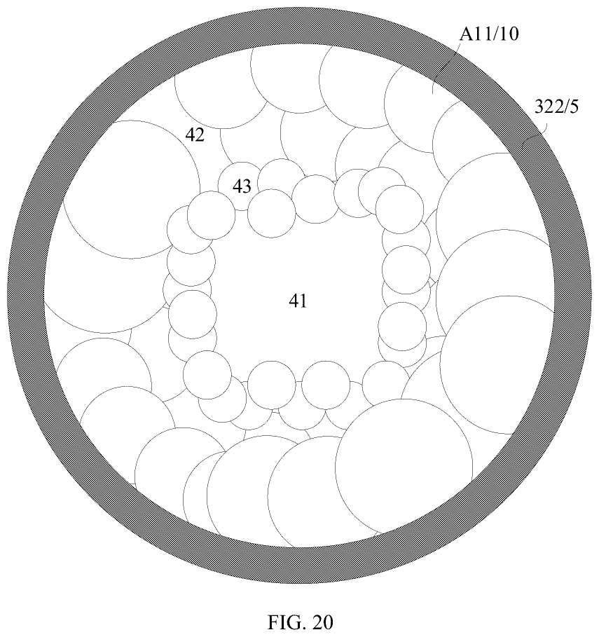

FIG. 20 is an enlarged schematic view of another light transmission region and its periphery according to some embodiments of the present disclosure. In some embodiments of the present disclosure, as shown in FIG. 20, multiple etching patterns 4 further include a third etching pattern 43 located between the first etching pattern 41 and the second etching pattern 42. The size of the first etching pattern 41 is greater than the size of the third etching pattern 43, and the size of the second etching pattern 42 is also greater than the size of the third etching pattern 43. In this embodiment, the third etching pattern 43 has a smallest size and functions as a supplementary etching pattern to fill the gap between the first etching pattern 41 and the second etching pattern 42. In this way, each region is comprises an etching pattern, the etching completeness of the display panel is ensured, the to-be-etched layer can be etched better, the etching effect of the display panel is ensured, and the display effect of the display panel is ensured.

In some embodiments of the present disclosure, as shown in FIG. 20, the first etching pattern 41, the second etching pattern 42, and the third etching pattern 43 are located in the same light transmission region A11. In some other embodiments, at least two of the first etching pattern 41, the second etching pattern 42, and the third etching pattern 43 are respectively located in different light transmission regions A11.

In some embodiments of the present disclosure, the edge of each of the first etching pattern 41, the second etching pattern 42, and the third etching pattern 43 includes a non-convex arc, and the number of the non-convex arc of the third etching pattern 43 is different from neither the number of the non-convex arc of the first etching pattern 41 nor the number of the non-convex arc of the second etching pattern 42. Therefore, the shape of the third etching pattern 43 is different from neither the shape of the first etching pattern 41 nor the shape of the second etching pattern 42. As a result, the distribution of multiple etching patterns 4 in the light transmission region A11 is more out of order, further improving the diffraction problem when external light passes through the first display sub-region A1.

FIG. 21 is an enlarged schematic view of another light transmission region according to some embodiments of the present disclosure. In some embodiments of the present disclosure, as shown in FIG. 21, the number of the non-convex arc of the third etching pattern 43 is greater than the number of the non-convex arc of the first etching pattern 41 and is also greater than the number of the non-convex arc of the second etching pattern 42. In this embodiment, the third etching pattern 41 has the largest amount of non-convex arc among the three etching patterns, so the laser spot corresponding to the third etching pattern 43 is surrounded by more laser spots, which improves the etching completeness and avoids presence of a position not etched by laser.

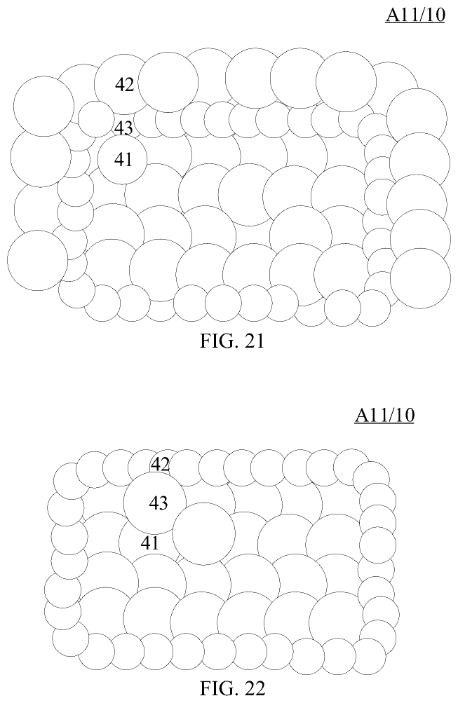

FIG. 22 is an enlarged schematic view of another light transmission region according to some embodiments of the present disclosure. In some alternative embodiments, as shown in FIG. 22, the number of the non-convex arc of the third etching pattern 43 is smaller than the number of the non-convex arc of the first etching pattern 41 and is also smaller than the number of the non-convex arc of the second etching pattern 42. In this embodiment, the third etching pattern 41 has the smallest amount of non-convex arc, so the laser spot corresponding to the third etching pattern 43 is formed later than the laser spot corresponding to the first etching pattern 41 and the laser spot corresponding to the second etching pattern 42. In this way, the laser spot corresponding to the third etching pattern 43 can fill the gap between the first etching pattern 41 and the second etching pattern 42 according to the position of the first etching pattern 41 and the position of the second etching pattern 42, thereby improving the etching completeness.

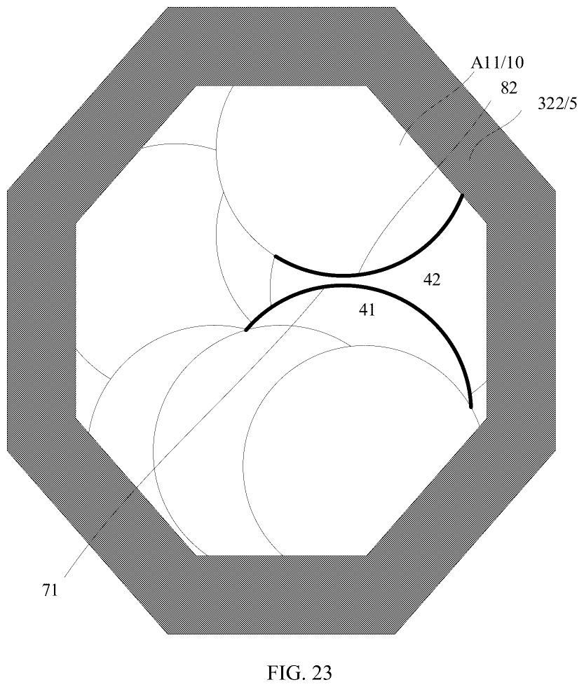

FIG. 23 is an enlarged schematic view of another light transmission region and its periphery according to some embodiments of the present disclosure. In some alternative embodiments, as shown in FIG. 23, the first etching pattern 41 is adjacent to the second etching pattern 42. In this embodiment, the first etching pattern 41 and the second etching pattern 42 are located in the same light transmission region A11 and adjacent to each other, and the first etching pattern 41 and the second etching pattern 42 have different shapes and/or sizes. In this way, the complexity and out-of-order degree of the distribution of multiple etching patterns 4 in the same light transmission region A11 are improved, so the diffraction problem when external light passes through the first display sub-region A1 can be better reduced or even eliminated. The first etching pattern 41 includes the first convex arc 71, and the second etching pattern 42 includes the second convex arc 72. For the first etching pattern 41 and the second etching pattern 42 that are arranged opposite to each other, the first convex arc 71 of the first etching pattern 41 may be regarded as one of the non-convex arcs of the second etching pattern 42.

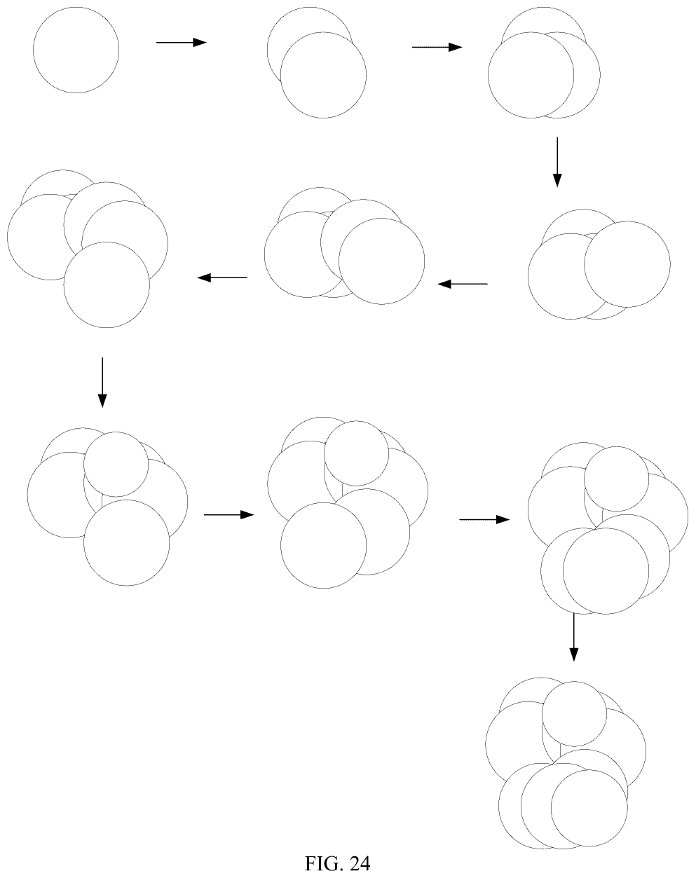

In some embodiments of the present disclosure, the first etching pattern 41 and the second etching pattern 42 that are located in the same light transmission region A11 and adjacent to each other have different shapes and/or sizes. FIG. 24 is a schematic diagram showing another etching sequence of a laser spot according to some embodiments of the present disclosure. For example, during the formation of the etching patterns shown in FIG. 23, as shown in FIG. 24, the irradiation of the laser spots may be carried out according to the irregular sequence shown in FIG. 24. The structure in the connection region or the light-emitting region in the periphery of the light transmission region is not shown in FIG. 24.

It should be noted that FIG. 24 shows an example laser spot having a circular shape, but in some embodiments of the present disclosure, one or more laser spots may be arranged in shapes other than circle according to different requirements.

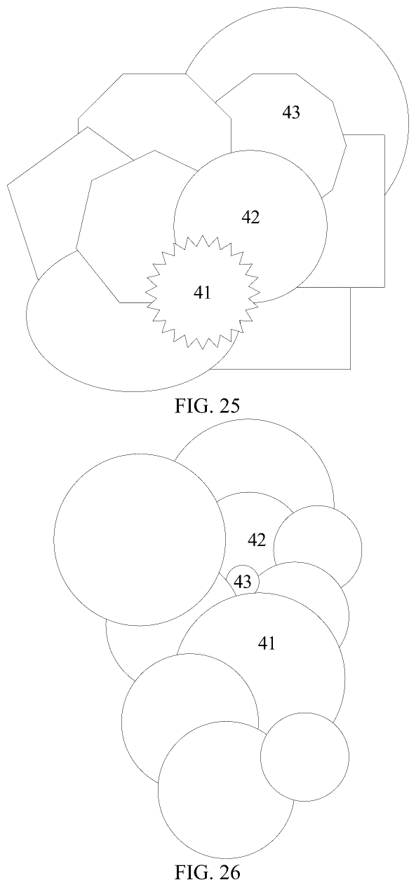

FIG. 25 is an enlarged schematic view of another light transmission region according to some embodiments of the present disclosure. In some embodiments of the present disclosure, as shown in FIG. 25, in addition to the first etching pattern 41 and the second etching pattern 42, multiple etching patterns 4 further include a third etching pattern 43. The shape of the third etching pattern 43 is different from the shape of the first etching pattern 41 nor the shape of the second etching pattern 42. As an example, the first etching pattern 41 includes a zigzag edge, the second etching pattern 42 includes an arc shape, and the third etching pattern 43 includes a straight edge.

FIG. 26 is an enlarged schematic view of another light transmission region according to some embodiments of the present disclosure. Additionally or alternatively, as shown in FIG. 26, the size of the third etching pattern 43 is different the same as the size of the first etching pattern 41 or the size of the second etching pattern 42. As an example, the edge of each of the first etching pattern 41, the second etching pattern 42, and the third etching pattern 43 includes an arc, and the area of the first etching pattern 41, the area of the second etching pattern 42, and the area of the third etching pattern 43 are different. The size of the third etching pattern 43 is different from neither the size of the first etching pattern 41 nor the size of the second etching pattern 42.

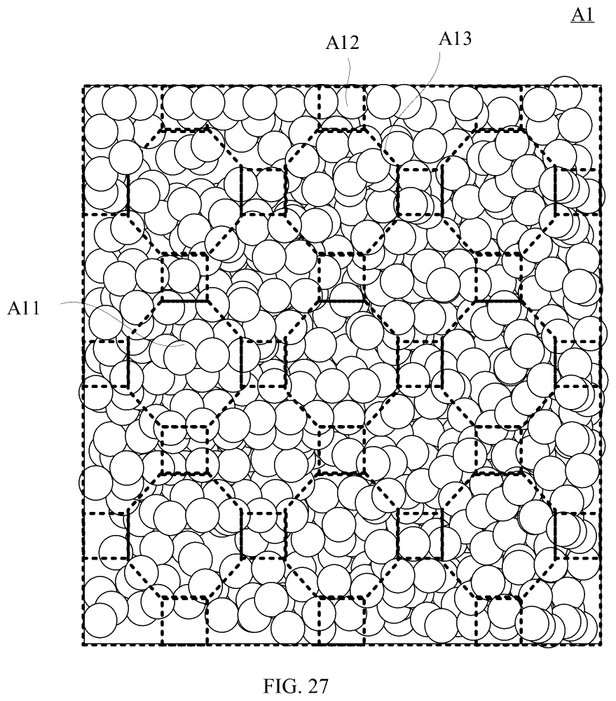

It should be noted that in the patterning process of the to-be-etched layer, in some embodiments of the present disclosure, the laser spot irradiates the to-be-etched layer in the first display sub-region A1. FIG. 27 is a schematic diagram showing distribution of laser spots irradiating the first display sub-region A1 according to some embodiments of the present disclosure. As shown in FIG. 27, the laser rays that are directed to the to-be-etched layer outside the light transmission region A11 will be blocked by the non-hollowed portion (not shown in FIG. 27) of the shielding layer, so the to-be-etched layer outside the light transmission region A11 receives no laser rays. Accordingly, no etching pattern is generated on the portions, arranged outside the light transmission region A11, of these layers. Or, in some embodiments of the present disclosure, the laser spot is only directed to the to-be-etched layer in the light transmission region A11.

Based on the same inventive concept, embodiments of the present disclosure further provide a method for manufacturing a display panel. With reference to FIG. 1, FIG. 2, FIG. 3, and FIG. 4, the display region AA includes a first display sub-region A1, the first display sub-region A1 includes at least one light transmission region A11, and the manufacturing method includes the following steps.

In step S1, a first layer 10 is formed.

In step S2, multiple etching patterns 4 are formed on the first layer 10 by etching the display panel using laser rays. The etching patterns 4 at least include a first etching pattern 41 and a second etching pattern 42. The first etching pattern 41 and the second etching pattern 42 have different shapes, and/or, the first etching pattern 41 and the second etching pattern 42 have different sizes.

In some embodiments of the present disclosure, the first etching pattern 41 and the second etching pattern 42 have different shapes, and/or, the first etching pattern 41 and the second etching pattern 42 have different sizes, so the etching patterns 4 have diversified designs, and different etching patterns 4 are irregularly distributed in the first display sub-region A1. When the external light passes through the first display sub-region A1, the diffraction phenomenon can be weakened or even eliminated, thereby improving the performance of the photosensitive device.

The etching patterns 4 having different shapes and or sizes are arranged in embodiments of the present disclosure. Accordingly, in the etching process of the display panel, laser spots having different shapes and/or sizes are employed to etch the to-be-etched layer. Compared with the etching method using a laser spot with a fixed size or shape, embodiments of the present disclosure have an advantage of improving the etching efficiency while ensuring the etching effect, so the manufacturing of the display panel is more efficient. Generally, by adjusting the sizes and/or the shapes of the etching patterns 4, the etching process having etching patterns 4 with different sizes and/or shapes is simpler and more efficient, reducing the manufacturing cost of the display panel. In the embodiments of the present disclosure, the etching pattern may be a remaining pattern generated by the etching process in the manufacturing of the display panel, for example, a laser etching pattern remained after the laser etching.

In some embodiments of the present disclosure, the step of forming multiple etching patterns 4 on the first layer 10 by etching the display panel using laser rays includes the following steps.

In step S21, a laser generator is provided.

In step S22, multiple laser spots are formed on the first layer by adjusting an etching path of the laser generator, and multiple etching patterns 4 are formed based on multiple laser spots.

In the etching process using a laser generator, one type of laser generator is used to etch the to-be-etched layer, for example, the cathode layer. In an embodiment, the laser spot generated by the laser generator irradiates the cathode layer so as to etch the region of the cathode layer corresponding to the light transmission region A11. After the cathode layer is etched, multiple laser etching patterns remain on the corresponding display function layer 320, that is, the display function layer 320 is the first layer.

In some embodiments of the present disclosure, the movement path of the laser spot is adjusted by adjusting the movement path of the laser generator, so that multiple etching patterns including the first etching pattern 41 and the second etching pattern 42 are formed on the first layer 10.

In some embodiments of the present disclosure, referring to FIG. 9, FIG. 10, FIG. 11 and FIG. 24, among multiple laser spots, at least one laser spot at least overlaps with its most adjacent laser spot. With such arrangement, on the one hand, the shape of the etching pattern can be adjusted using two laser spots having adjacent positions, reducing the diffraction, and on the other hand, an ignored region not irradiated by the laser spot is avoided, improving the etching completeness.

In some embodiments of the present disclosure, the etching path for forming the first etching pattern 41 is different from the etching path for forming the second etching pattern 42, so the first etching pattern 41 and the second etching pattern 42 have different shapes. For example, during the formation of the first etching pattern 41 with the structure shown in FIG. 4, the first movement path of the laser generator is a spiral curve. During the formation of the second etching pattern 42, the second movement path of the laser generator is different from the first movement path. For example, the second movement path may be according to the out-of-order design shown in FIG. 23. With such arrangement, on the one hand, the first etching pattern 41 and the second etching pattern 42 have different shapes and/or different sizes, on the other hand, curve arrangement can ensure that the laser spots are compactly arranged. In this way, an ignored region in the first light transmission region A11 not irradiated by the laser spot is avoided, a completeness etching is carried out in the region that needs to be etched, residual foreign matters are avoided, and the light transmission effect and the overall display effect of the display panel are ensured. In addition, the etching path is a spiral curve, which can avoid multiple laser irradiations in the same region and avoid over etching.

In some embodiments of the present disclosure, the step of forming multiple etching patterns 4 on the first layer 10 by etching the display panel using laser rays includes the following steps. A laser generator is provided. A distance between the laser generator and the first layer 10 is adjusted to form, on the first layer 10, multiple laser spots having different areas. Multiple etching patterns 4 are formed based on multiple laser spots having different areas. In this embodiment, the distance between the laser generator and the to-be-etched layer is adjusted by adjusting the distance between the laser generator and the first layer 10, so the size of the laser spot emitted by the laser generator and transmitted to the to-be-etched layer is changed, thereby achieving the different shapes of the first etching pattern 41 and the second etching pattern 42 remained on the first layer 10.

In some embodiments of the present disclosure, the step of forming multiple etching patterns 4 on the first layer 10 by etching the display panel using laser rays includes the following steps.

At least two laser generators are provided. Laser spots provided by different laser generators have different sizes or shapes.

Positions of the laser spots provided by different laser generators are controlled, and multiple etching patterns 4 are formed on the first layer 10 based on the at least two laser generators.

In an embodiment, two laser generators are provided in the etching process, and different laser generators can provide laser spots having different shapes or laser spots having the same shape but different sizes. Based on the diversity of the laser spots, the arrangement of the laser spots remained on the first layer 10 after the etching process is diversified, reducing the diffraction.

In some embodiments of the present disclosure, referring to FIG. 18, FIG. 19 and FIG. 25, two or more laser generators are used to etch the to-be-etched layer, and different laser generators can provide laser spots having different sizes, so the first etching pattern 41 and the second etching pattern 42 having different sizes and different shapes are formed on the first layer 10.

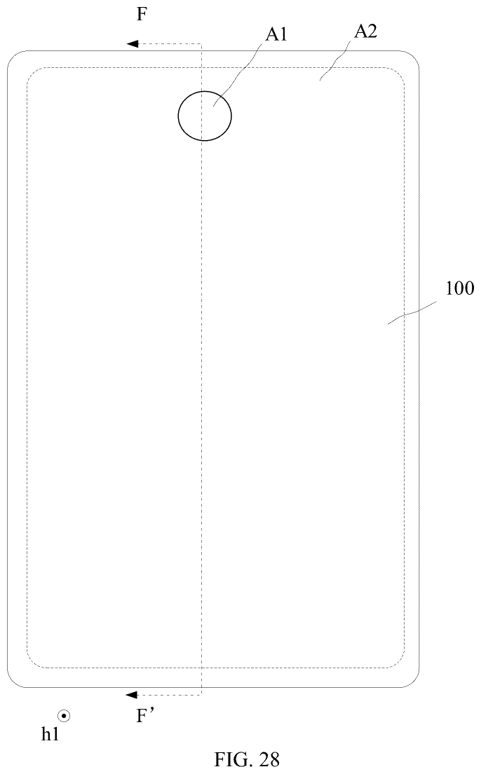

The present disclosure further provides a display apparatus. FIG. 28 is a schematic diagram of a display apparatus according to an embodiment of the present disclosure. The display apparatus includes the above display panel 1000. The specific structure of the display panel 1000 has been described in detail in foregoing embodiments, and will not be elaborated here. It is appreciated that the display apparatus shown in FIG. 28 is only for schematic illustration. The display apparatus may be any electronic apparatus having a display function, such as a mobile phone, a tablet computer, a laptop computer, an electronic paper book, or a television.

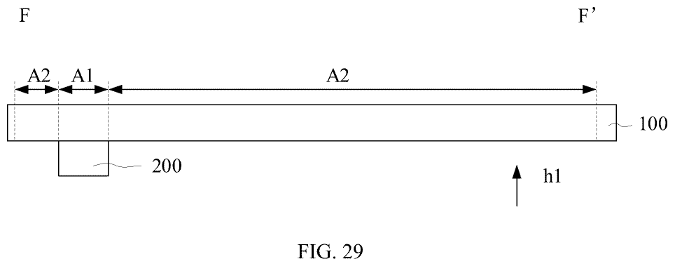

FIG. 29 is a cross-sectional view taken along line FF′ in FIG. 28. In some embodiments of the present disclosure, as shown in FIG. 29, the display panel further includes a photosensitive device 200. The photosensitive device 200 is disposed corresponding to the first display sub-region A1. For example, the photosensitive device 200 is below the first display sub-region A1. When the photosensitive device 200 works, ambient light passes through the first display sub-region A1 and is incident on the photosensitive device 200. According to the arrangement of embodiments of the present disclosure, the light transmittance of the first display sub-region A1 is improved, and accordingly the performance of the photosensitive device 200 is ensured.

The above are merely exemplary embodiments of the present disclosure, and are not intended to limit the present disclosure. Those skilled in the art can make various modifications and changes to the embodiments of the present disclosure. Any modification, equivalent replacement, improvement and the like within the spirit and principle of the present disclosure all fall within the protection scope of the present disclosure.

What is claimed is:

1. A display panel, comprising: a display region,
wherein the display region comprises a first display sub-region, the first display sub-region comprises at least one light transmission region,
wherein the display panel comprises a first layer, at least a part of the first layer is located in the at least one light transmission region, the first layer comprises etching patterns, and the etching patterns comprise first etching patterns and second etching patterns, and
wherein the first etching patterns define a different shape and/or size from the second etching patterns.

2. The display panel according to claim 1, wherein a single transmission region of the at least one light transmission region comprises the first etching patterns and the second etching patterns.

3. The display panel according to claim 1, wherein the first display sub-region comprises at least two light transmission regions, one of the at least two light transmission regions comprises the first etching patterns, and another one of the at least two light transmission regions comprises the second etching patterns.

4. The display panel according to claim 1, wherein an edge of one of the first etching patterns comprises a first convex arc, an edge of one of the second etching patterns comprises a second convex arc, and the first convex arc and the second convex arc are respectively located at different sides of the first etching patterns and the second etching patterns.

5. The display panel according to claim 1, wherein an edge of one of the first etching patterns comprises at least one first non-convex arc, an edge of one of the second etching patterns comprises at least one second non-convex arc, and a number of the at least one first non-convex arc is not equal to a number of the at least one second non-convex arc.

6. The display panel according to claim 5, wherein the number of the at least one first non-convex arc is smaller than the number of the at least one second non-convex arc, and the first etching patterns are located at a side of the second etching patterns away from a center of the light transmission region.

7. The display panel according to claim 5, wherein the number of the at least one first non-convex arc is smaller than the number of the at least one second non-convex arc, and the first etching patterns are located at a side of the second etching patterns away from the edge of at least one light transmission region.

8. The display panel according to claim 1, wherein one of the at least one light transmission region comprises a first region and a second region, and a density of the etching patterns in the first region is different from a density of the etching patterns in the second region.

9. The display panel according to claim 8, wherein the density of the etching patterns in the first region is greater than the density of the etching patterns in the second region, and the first region is located at a side of the second region away from a center of the light transmission region.

10. The display panel according to claim 1, wherein the shape of the first etching pattern is different from the shape of the second etching pattern, and the first etching pattern is located at a side of the second etching pattern facing toward an edge of the light transmission region.

11. The display panel according to claim 10, wherein the first etching patterns comprise a dot-shaped etching pattern, and the second etching patterns comprise a block-shaped etching patterns or a strip-shaped etching patterns.

12. The display panel according to claim 1, wherein an area of one of the first etching patterns is different than an area of one of the second etching patterns, and the first etching patterns are located at a side of the second etching patterns facing toward an edge of the first display sub-region.

13. The display panel according to claim 12, wherein the area of one of the first etching patterns is smaller than the area of one of the second etching patterns.

14. The display panel according to claim 1, wherein the etching patterns further comprise a third etching pattern located between one of the first etching patterns and one of the second etching patterns, and a size of the third etching pattern is smaller than the size of one of the first etching patterns and is smaller than the size of one of the second etching patterns.

15. The display panel according to claim 1, wherein the etching patterns further comprise a third etching pattern located between one of the first etching patterns and one of the second etching patterns, and each of the first etching pattern, the second etching pattern, and the third etching pattern comprises an edge comprising a non-convex arc, and
a number of the non-convex arc in the third etching pattern is greater than a number of the non-convex arc in one of the first etching patterns and is greater than a number of the non-convex arc in one of the second etching patterns, or the number of the non-convex arc in the third etching pattern is smaller than the number of the non-convex arc in one of the first etching patterns and is smaller than the number of the non-convex arc in one of the second etching patterns.

16. The display panel according to claim 1, wherein one of the first etching patterns is adjacent to one of the second etching patterns.

17. The display panel according to claim 1, wherein the etching patterns further comprise a third etching pattern, and
wherein a shape of the third etching pattern is different from neither the shape of one of the first etching patterns and the shape of one of the second etching patterns, and/or, a size of the third etching pattern is different from neither the size of one of the first etching patterns and the size of one of the second etching patterns.

18. The display panel according to claim 1, wherein the at least one light transmission region comprises fourth etching patterns, and an edge of one of fourth etching patterns does not include a convex arc.

19. The display panel according to claim 1, wherein the first display sub-region further comprises light-emitting regions, one of the light-emitting regions comprises a first light-emitting element, and the first light-emitting element comprises an anode, a light-emitting layer, and a cathode that are stacked on one another,
wherein the display panel further comprises a cathode contact layer, and the cathode contact layer comprises a first sub-portion located in the light transmission region and a second sub-portion located in the light-emitting regions, and
wherein the first sub-portion comprises the first layer, and the second sub-portion is in contact with the cathode.

20. The display panel according to claim 19, wherein the cathode contact layer comprises an electron injection layer or an electron transport layer.

21. The display panel according to claim 19, wherein the first display sub-region further comprises a connection region between two adjacent light-emitting regions of the light-emitting regions, the connection region comprises a connection portion, and the cathode contact layer further comprises a third sub-portion that is located in the connection region and is in contact with the connection portion.

22. The display panel according to claim 1, further comprising a shielding layer located at a side of the first layer facing toward the substrate, wherein the shielding layer comprises a hollowed portion and a non-hollowed portion; and
wherein the hollowed portion overlaps with one of the at least one light transmission region along a thickness direction of the display panel.

23. A method for manufacturing a display panel, wherein a display region of the display panel comprises a first display sub-region, the first display sub-region comprises at least one light transmission region, and the method comprises:
providing a first layer; and
etching the display panel with laser rays thereby forming etching patterns on the first layer, wherein the etching patterns at least comprise first etching patterns and second etching patterns,
wherein the first etching patterns comprise a different shape and/or size from the second etching pattern.

24. The method according to claim 23, wherein the etching the display panel with laser rays thereby forming etching patterns on the first layer comprises:
providing a laser generator; and
adjusting an etching path of the laser generator to form laser spots on the first layer defining the etching patterns based on the laser spots.

25. The method according to claim 24, wherein at least one of the laser spots at least overlaps with its most adjacent laser spot of the laser spots.

26. The method according to claim 24, wherein the etching path for forming the first etching pattern is different from the etching path for forming the second etching pattern.

27. The method according to claim 24, wherein the etching the display panel by using laser rays thereby forming etching patterns on the first layer comprises:
providing a laser generator; and
adjusting a distance between the laser generator and the first layer to form, on the first layer, laser spots having different areas, and forming the etching patterns based on the laser spots having different areas.

28. The method according to claim 24, wherein the etching the display panel using laser rays thereby forming etching patterns on the first layer comprises:
providing at least two laser generators, wherein laser spots provided by the at least two laser generators have different sizes or shapes; and
controlling positions of the laser spots provided by the at least two laser generators, and forming the etching patterns on the first layer based on the at least two laser generators.

29. A display apparatus, comprising: a display panel, wherein the display panel comprises
a display region,
wherein the display region comprises a first display sub-region, the first display sub-region comprises at least one light transmission region,
wherein the display panel comprises a first layer, at least a part of the first layer is located in the at least one light transmission region, the first layer comprises etching patterns, and the etching patterns at least comprise first etching patterns and second etching patterns, and
wherein the first etching patterns have a different shape and/or a size from the second etching patterns.
